(19) United States
(12) Patent Application Publication
(10) Pub. No.: US 2019/0367775 A1
(43) Pub. Date: Dec. 5, 2019

(54) POLISHING SLURRY COMPOSITION

(71) Applicant: KCTECH CO., LTD., Gyeonggi-do (KR)

(72) Inventors: Hyungoo KONG, Gyeonggi-do (KR); Junghun KIM, Gyeonggi-do (KR); Jinsook HWANG, Gyeonggi-do (KR)

(21) Appl. No.: 16/423,420

(22) Filed: May 28, 2019

(30) Foreign Application Priority Data
Jun. 1, 2018 (KR) 10-2018-0063656
Aug. 2, 2018 (KR) 10-2018-0090442

(51) Int. Cl. C09G 1/02

(52) U.S. Cl. CPC C09G 1/02; H01L 21/31055

(57) ABSTRACT

Provided is a polishing slurry composition including iron-substituted abrasive particles, a pH adjusting agent, and a chelating agent.

### CROSS-REFERENCE TO RELATED APPLICATION(S)

This application claims the benefit of Korean Patent Application No. 10-2018-0063656 filed on Jun. 1, 2018, and Korean Patent Application No. 10-2018-0090442 filed on Aug. 2, 2018, in the Korean Intellectual Property Office, the disclosures of which are incorporated herein by reference for all purposes.

### BACKGROUND

### 1. Field of the Invention

One or more example embodiments relate to a polishing slurry composition for a semiconductor device and a display device.

### 2. Description of the Related Art

Recently, there have been required a number of chemical mechanical polishing (CMP) processes for many thin films constituting devices in the field of semiconductor and display industries.

A CMP process refers to a process of smoothly polishing a surface of a semiconductor wafer using a slurry containing an abrasive and various compounds through a rotation movement while the surface of the semiconductor wafer is in contact with a polishing pad. In general, it is known that a metal polishing process is performed by repeating a process of forming a metal oxide (MOₓ) by an oxidizer and a process of removing the formed metal oxide with abrasive particles.

A polishing process of a tungsten layer, which is widely used as a wiring of a semiconductor device, is also performed by a mechanism in which a process of forming a tungsten oxide (WO3) by an oxidizer and a potential control agent and a process of removing the tungsten oxide with abrasive particles are repeated. Also, an insulation film or a pattern such as a trench may be formed under the tungsten layer. In this case, a high polishing selectivity between the tungsten layer and the insulation film is required in the CMP process. Thus, in order to improve the polishing selectivity of tungsten with respect to the insulation film, various components are added to a slurry, or amounts of an oxidizer and a catalyst to be contained in the slurry are controlled. However, in spite of such endeavor, a tungsten polishing slurry which implements a high polishing selectivity or improves a polishing performance by adjusting a desired polishing selectivity has not been developed yet.

Further, indium tin oxide (ITO), indium zinc oxide (MO), or indium tin zinc oxide (ITZO) is widely used as an inorganic substance with high conductivity and light transmittance. This is used as a thin layer of ITO covering a substrate surface in a display device, a display substrate and panel such as an organic light emitting diode (OLED), a touch panel, a transparent electrode for a solar cell, or an antistatic film. In general, to deposit an ITO thin film on a substrate, physical vapor depositions such as DC-magnetron sputtering, RF-sputtering, ion beam sputtering and e-beam evaporation, and chemical vapor depositions such as sol-gel and spray pyrolysis are used. A thin film formed by DC-magnetron sputtering, which is most widely used among the above depositions, has a high surface roughness of more than Rrms 1 nm or more than Rpv 20 nm. Thus, when the thin film is applied to an organic light emitting diode, an organic substance is damaged due to a concentration of current density, which results in defects such as block spots. In conjunction with non-uniform scratches and surface residues (foreign substances adsorbed on the ITO surface) of the ITO thin film, a current leakage path through a diode adjacent to the ITO layer may be provided, which causes a crosstalk and a low resistance.

Attempts have been made to solve the issues mentioned above through planarization of the ITO film. Representatively, ion beam sputtering and ion plating are used. However, such ion assisted depositions may be used to deposit a thin film having a flat surface, but may be difficult to be applied to mass production due to a slow deposition rate and difficulties in increasing the area. Although suggested in a method of performing planarization by finely polishing a surface of a formed thin film, a planarization method by a rod member having a surface with abrasive ability, application of a liquid planarizing agent using surface modifier deposition, planarization etching, pressure planarization, and ablation, existing planarization processes by polishing, surface modifier deposition, and etching cause unwanted scratch defects or surface contamination on the surface of the ITO film after the planarization processes are performed.

### SUMMARY

An aspect provides, to solve the foregoing issues, a polishing slurry composition including iron-substituted abrasive particles that may improve a surface planarization process of a thin film applied to a semiconductor device and a display device.

According to an aspect, there is provided a polishing slurry composition including iron-substituted abrasive particles, a pH adjusting agent, and a chelating agent, an oxidizer, or both.

The iron-substituted abrasive particles may be included in the slurry composition in an amount of 0.0001 parts by weight to 20 parts by weight.

The iron-substituted abrasive particles may be included in the slurry composition in an amount of more than 0.5 parts by weight and less than or equal to 5 parts by weight.

The iron-substituted abrasive particles may range in size from 10 nm to 300 nm.

The iron-substituted abrasive particles may be iron-substituted at an atomic site positioned in a length region of less than or equal to 30% from a surface of the iron-substituted abrasive particles, in a length (100%) from the surface to a center of the iron-substituted abrasive particles.

The iron-substituted abrasive particles may include at least one of a metal oxide, and a metal oxide coated with an organic substance or an inorganic substance, the metal oxide may be in a colloidal state, and the metal oxide may include at least one of silica, ceria, zirconia, alumina, titania, barium titania, germania, manganese, and magnesia.

The iron-substituted abrasive particles may include an iron ion having a tetrahedral coordination, and the iron-substituted abrasive particles may include a metal (M)-O—Fe bond, a metal (M)-Fe bond, or both, M being selected from Si, Ce, Zr, Al, Ti, Ba, Ge, Mn, and Mg.

The iron-substituted abrasive particles may have a zeta potential of −1 mV to −100 mV at a pH of 1 to 12.

The iron-substituted abrasive particles may include particles with a single size of 10 nm to 300 nm or mixed particles with at least two different sizes of 10 nm to 300 nm.

The iron-substituted abrasive particles may include particles with a first size of 10 nm to 150 nm and a second size of 150 nm to 300 nm.

The chelating agent may include an organic acid, and the organic acid may include at least one of citric acid, malic acid, maleic acid, malonic acid, oxalic acid, succinic acid, lactic acid, tartaric acid, adipic acid, pimelic acid, suberic acid, azelaic acid, sebacic acid, maleic acid, fumaric acid, acetic acid, adipic acid, butyric acid, capric acid, caproic acid, caprylic acid, glutaric acid, glycolic acid, formic acid, lauric acid, myristic acid, palmitic acid, phthalic acid, propionic acid, pyruvic acid, stearic acid, and valeric acid.

The chelating agent may be included in the slurry composition in an amount of 0.00001 parts by weight to 10 parts by weight.

The oxidizer may include at least one of hydrogen peroxide, urea hydrogen peroxide, urea, percarbonate, periodic acid, periodate, perchloric acid, perchlorate, perbromic acid, perbromate, perboric acid, perborate, permanganic acid, permanganate, persulfate, bromate, chlorate, chlorite, chromate, iodate, iodic acid, ammonium peroxodisulfate, benzoyl peroxide, calcium peroxide, barium peroxide, sodium peroxide, and carbamide peroxide.

The oxidizer may be included in the slurry composition in an amount of 0.00001 parts by weight to 10 parts by weight.

The pH adjusting agent may include an acidic substance or a basic substance, the acidic substance may include at least one of nitric acid, hydrochloric acid, phosphoric acid, sulfuric acid, hydrofluoric acid, bromic acid, iodic acid, formic acid, malonic acid, maleic acid, oxalic acid, acetic acid, adipic acid, citric acid, propionic acid, fumaric acid, salicylic acid, pimelic acid, benzoic acid, succinic acid, phthalic acid, butyric acid, glutaric acid, glutamic acid, glycolic acid, lactic acid, aspartic acid, tartaric acid, and salts thereof, and the basic substance may include at least one of ammonium methyl propanol (AMP), tetra methyl ammonium hydroxide (TMAH), ammonium hydroxide, potassium hydroxide, sodium hydroxide, magnesium hydroxide, rubidium hydroxide, cesium hydroxide, sodium bicarbonate, sodium carbonate, imidazole, and salts thereof.

The polishing slurry composition may be applied to polishing of a thin film including at least one of a silicon oxide film, a metal film, a metal oxide film, and an inorganic oxide film.

The polishing slurry composition may be applied to a polishing process of a semiconductor device, a display device, or both.

The metal film and the metal oxide film may each include at least one of Indium (In), tin (Sn), silicon (Si), titanium (Ti), vanadium (V), gadolinium (Gd), gallium (Ga), manganese (Mn), iron (Fe), cobalt (Co), copper (Cu), zinc (Zn), zirconium (Zr), hafnium (Hf), aluminum (Al), niobium (Nb), nickel (Ni), chromium (Cr), molybdenum (Mo), tantalum (Ta), ruthenium (Ru), tungsten (W), titanium (Ti), neodymium (Nd), rubidium (Rb), gold (Au), and platinum (Pt).

The inorganic oxide film may include at least one of fluorine doped tin oxide (FTO, SnO₂:F), indium tin oxide (ITO), indium zinc oxide (IZO), indium gallium zinc oxide (IGZO), Al-doped ZnO (AZO), aluminum gallium zinc oxide (AGZO), Ga-doped ZnO (GZO), indium zinc tin oxide (IZTO), indium aluminum zinc oxide (IAZO), indium gallium tin oxide (IGTO), antimony tin oxide (ATO), gallium zinc oxide (GZO), IZO nitride (IZON), SnO₂, ZnO, RuOx, and NiO.

A target film may be polished using the polishing slurry composition at a speed of greater than or equal to 100 Å/min.

A degree of planarization of a surface of a target film after polishing is performed using the slurry composition may be less than or equal to 5%.

A transparency of a device after a target film is polished using the slurry composition may increase by 5% or more when compared to that before the target film is polished.

Additional aspects of example embodiments will be set forth in part in the description which follows and, in part, will be apparent from the description, or may be learned by practice of the disclosure.

### Effect

According to example embodiments, it is possible to provide a polishing slurry composition that may secure a sufficient polishing rate for each film to be polished by applying iron-substituted abrasive particles, and free or minimize scratch defects during a polishing process.

The polishing slurry composition may be applied to a planarization process of a semiconductor device and a display device through a chemical mechanical polishing (CMP) process, in detail, a planarization process of an insulation film, an oxide film, a semiconductor film, an inorganic oxide film used for the semiconductor device, and an inorganic oxide film used for the display device.

The polishing slurry composition may secure a degree of planarization and/or a transmittance of a semiconductor wiring device, a display substrate, or a panel requiring a planarization process of an oxide film, a metal film, and an inorganic oxide film, thereby increasing an efficiency for post-processing.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a mimetic diagram illustrating a colloidal silica abrasive particle substituted with an iron (Fe) ion by hydrothermal synthesis according to an example embodiment.

### DETAILED DESCRIPTION

Hereinafter, example embodiments will be described in detail with reference to the accompanying drawings. However, the scope of the present application is not limited to the example embodiments. In the drawings, like reference numerals are used for like elements.

The terminology used herein is for the purpose of describing particular examples only and is not to be limiting of the examples. As used herein, the singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which examples belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the example embodiments with reference to the accompanying drawings, like reference numerals refer to like constituent elements and a repeated description related thereto will be omitted. When it is determined detailed description related to a related known function or configuration they may make the purpose of the example embodiments unnecessarily ambiguous in describing the example embodiments, the detailed description will be omitted here.

One or more example embodiments relate to a polishing slurry composition. The slurry composition may include iron-substituted abrasive particles, a pH adjusting agent, and a chelating agent, an oxidizer, or both.

The iron-substituted abrasive particles may be included in the slurry composition in an amount of 0.0001 parts by weight to 20 parts by weight. The iron-substituted abrasive particles may improve a transparency and/or a degree of planarization after polishing is performed, and minimize imperfections such as a defect and a scratch. The iron-substituted abrasive particles may be preferably in an amount of 0.0001 parts by weight to 10 parts by weight, and more preferably in an amount of more than 0.5 parts by weight and less than or equal to 5 parts by weight.

The iron-substituted abrasive particles may be abrasive particles with a portion substituted with an iron ion. The iron-substituted abrasive particles may modify a surface by substituting a metal oxide element ion (for example, an Si ion if the abrasive particles are silica, Ce if the abrasive particles are ceria, or Zr if the abrasive particles are zirconia) of the surface of the abrasive particles with an iron ion under hydrothermal synthesis conditions, using a characteristic of the iron ion having a tetrahedral coordination in an alkaline region, thereby improving the dispersion stability even in an acidic region and increasing negative electric charges of the slurry composition, and thus freeing or minimizing scratch defects during polishing.

The iron-substituted abrasive particles may be substituted with an iron ion at an atomic site positioned in a length region of less than or equal to 30% from a surface of the iron-substituted abrasive particles, in a length (100%) from the surface to a center of the iron-substituted abrasive particles. The iron (Fe) ion may substitute for a component of the portion of the abrasive particles on and/or in the surface of the abrasive particles.

The iron-substituted abrasive particles may include at least one of a metal oxide, and a metal oxide coated with an organic substance or an inorganic substance, and the iron-substituted abrasive particles and/or the metal oxide may be in a colloidal state. The metal oxide may include at least one of silica, ceria, zirconia, alumina, titania, barium titania, germania, manganese, and magnesia.

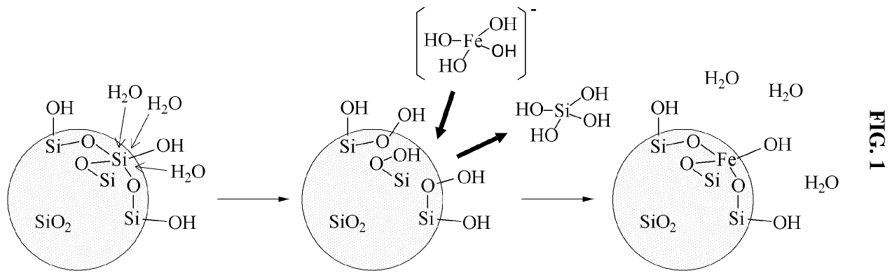

The iron ion may have a tetrahedral coordination, and the iron-substituted abrasive particles may include a metal (M)-O—Fe bond, a metal (M)-Fe bond, or both. Here, the metal M may include at least one of Si, Ce, Zr, Al, Ti, Ba, Ge, Mn, and Mg. For example, FIG. 1 is a mimetic diagram illustrating a colloidal silica abrasive particle substituted with an iron (Fe) ion according to an example embodiment. Referring to FIG. 1, it may be verified that one of silicon (Si) ions in a colloidal silica abrasive particle is substituted with an iron (Fe) ion, and includes Si—O—Fe and Si—Fe.

The iron-substituted abrasive particles may range in size from 10 nm to 300 nm. When the size of the particles is less than 10 nm, small particles are generated excessively, the planarity of a film to be polished decreases, and a polishing rate decreases due to an excess of defects occurring on the surface of the film to be polished. When the size of the particles exceeds 300 nm, monodispersibility may not be achieved, and it may be difficult to adjust a degree of planarization, a transparency, and a defect after mechanical polishing is performed. The size of the particles may refer to a diameter, a length, or a thickness depending on a shape of the particles.

The iron-substituted abrasive particles may include, to improve a dispersibility in a slurry, a polishing performance of the film to be polished, a degree of planarization, and a transparency, particles with a single size of 10 nm to 300 nm or mixed particles with at least two different sizes of 10 nm to 300 nm. For example, the iron-substituted abrasive particles may include particles with a first size of 10 nm to 150 nm and a second size of 150 nm to 300 nm.

The shape of the iron-substituted abrasive particles may include at least one of a spherical shape, a rectangular shape, a needle shape, and a plate shape.

The iron-substituted abrasive particles may have a zeta potential of −1 mV to −100 mV at a pH of 1 to 12, a zeta potential of −10 mV to −70 mV at a pH of 1 to 6, or a zeta potential of −10 mV to −70 mV at a pH of 2.5 to 6. This results in a high zeta potential absolute value even in an acidic region, which leads to a high dispersion stability and an excellent polishing performance with respect to the film to be polished.

The iron-substituted abrasive particles may function as abrasive particles in the polishing slurry composition and function as an oxidizer which oxidizes a metal film at the same time.

The iron-substituted abrasive particles may modify a surface by substituting a metal oxide element ion (for example, an Si ion if the abrasive particles are silica, Ce if the abrasive particles are ceria, or Zr if the abrasive particles are zirconia) of the surface of the abrasive particles with an iron ion under hydrothermal synthesis conditions, using a characteristic of a metal ion having a tetrahedral coordination in an alkaline region, thereby preparing a polishing slurry composition with a high dispersion stability. Further, the iron ion substituting the metal oxide element ion on the surface of the abrasive particles may implement a high polishing characteristic of accelerating oxidation of the film to be polished, for example, an inorganic oxide film to easily polish the inorganic oxide film, and minimize scratch defects, thereby improving a degree of planarization and a transparency of the inorganic oxide film such as an ITO film.

A method of preparing iron-substituted abrasive particles may include an operation of preparing a mixture by mixing abrasive particles with an iron-containing salt, a metal ion compound, or both, and an operation of synthesizing the mixture under hydrothermal synthesis conditions.

The method of preparing the metal-substituted abrasive particles is substituting a metal oxide element ion of the abrasive particles with an iron ion using a characteristic of a metal ion having a tetrahedral coordination under alkaline conditions.

The iron-containing salt may include at least one of ferric nitrate (Fe(NO₃)₃), ferric sulfate (Fe₂(SO₄)₃), ferric oxide (Fe₂O₃), and ferric chloride (FeCl₃). Ferric nitrate dissolves in water to produce iron ions Fe²⁺ and Fe³.

The metal ion compound may include at least one of sodium nitrate, lithium nitrate, potassium nitrate, sodium hydroxide, lithium hydroxide, potassium hydroxide, sodium sulfate, lithium sulfate, potassium sulfate, sodium chloride, lithium chloride, potassium chloride, sodium carbonate, lithium carbonate, and potassium carbonate.

The iron-containing salt may be in an amount of 0.001 parts by weight to 20 parts by weight based on 100 parts by weight of the abrasive particles. When the amount of the metallic salt is less than 0.001 parts by weight, it may be difficult to obtain a sufficient zeta potential, and thus the dispersion stability may decrease. When the amount of the metallic salt exceeds 20 parts by weight, an unreacted iron-containing salt may cause contamination.

The metal ion compound may be in an amount of 0.001 parts by weight to 20 parts by weight based on 100 parts by weight of the abrasive particles. When the amount of the metal ion compound is less than 0.001 parts by weight, iron ion substitution may not be performed smoothly. When the amount of the metal ion compound exceeds 20 parts by weight, contamination may occur, and thus the dispersion stability may decrease.

The operation of synthesizing the mixture under hydrothermal synthesis conditions, performed to efficiently proceed with ion substitution reaction, may be an operation of performing hydrothermal synthesis for 0.5 hours to 72 hours in the temperature range of 100° C. to 300° C.

Before the hydrothermal synthesis is performed, a pH of the mixture may be adjusted to 9 to 12. After the hydrothermal synthesis is completed, the pH may be adjusted to 1 to 5. In this example, an acid or a base may be used as the pH adjusting agent without restriction. For example, at least one of potassium hydroxide, sodium hydroxide, ammonia, ammonia derivatives, hydrochloric acid, nitric acid, sulfuric acid, phosphoric acid, boric acid, amino acid, citric acid, formic acid, maleic acid, oxalic acid, tartaric acid, and acetic acid may be used in an amount suitable to adjust the pH.

For example, FIG. 1 is a mimetic diagram illustrating a colloidal silica abrasive particle substituted with an iron (Fe) ion by hydrothermal synthesis according to an example embodiment. FIG. 1 shows a process of substituting one of silicon (Si) ions in a colloidal silica abrasive particle with an iron (Fe) ion. The process is performed using a characteristic of the iron (Fe) ion having a tetrahedral coordination under alkaline conditions. It may be verified that one of the silicon (Si) ions is substituted with an iron (Fe) ion through an efficient metal substitution reaction under hydrothermal synthesis conditions after ferric nitrate (Fe(NO₃)₃) as a metallic salt and sodium nitrate as a metal ion compound are mixed.

The chelating agent may include an organic acid, and the organic acid may include at least one of citric acid, malic acid, maleic acid, malonic acid, oxalic acid, succinic acid, lactic acid, tartaric acid, adipic acid, pimelic acid, suberic acid, azelaic acid, sebacic acid, maleic acid, fumaric acid, acetic acid, adipic acid, butyric acid, capric acid, caproic acid, caprylic acid, glutaric acid, glycolic acid, formic acid, lauric acid, myristic acid, palmitic acid, phthalic acid, propionic acid, pyruvic acid, stearic acid, and valeric acid.

The chelating agent may be included in the slurry composition in an amount of 0.00001 parts by weight to 10 parts by weight, and the particle dispersibility and the stability of the slurry composition may be secured, if within the range.

The pH adjusting agent is to prevent corrosion of the film to be polished or corrosion of a polishing machine and to implement a pH range suitable for the polishing performance. The pH adjusting agent may include an acidic substance or a basic substance. The acidic substance may include at least one of nitric acid, hydrochloric acid, phosphoric acid, sulfuric acid, hydrofluoric acid, bromic acid, iodic acid, formic acid, malonic acid, maleic acid, oxalic acid, acetic acid, adipic acid, citric acid, propionic acid, fumaric acid, salicylic acid, pimelic acid, benzoic acid, succinic acid, phthalic acid, butyric acid, glutaric acid, glutamic acid, glycolic acid, lactic acid, aspartic acid, tartaric acid, and salts thereof. The basic substance may include at least one of ammonium methyl propanol (AMP), tetra methyl ammonium hydroxide (TMAH), ammonium hydroxide, potassium hydroxide, sodium hydroxide, magnesium hydroxide, rubidium hydroxide, cesium hydroxide, sodium bicarbonate, sodium carbonate, imidazole, and salts thereof.

The oxidizer may include at least one of hydrogen peroxide, urea hydrogen peroxide, urea, percarbonate, periodic acid, periodate, perchloric acid, perchlorate, perbromic acid, perbromate, perboric acid, perborate, permanganic acid, permanganate, persulfate, bromate, chlorate, chlorite, chromate, iodate, iodic acid, ammonium peroxodisulfate, benzoyl peroxide, calcium peroxide, barium peroxide, sodium peroxide, and carbamide peroxide.

The oxidizer may be included in the slurry composition in an amount of 0.00001 parts by weight to 10 parts by weight. If within the range, a polishing speed suitable for the film to be polished may be provided, and surface hardening, erosion occurrence, and corrosion of the film to be polished caused by an increase in the oxidizer content may be prevented.

A pH of the polishing slurry composition may be adjusted to provide the dispersion stability and the suitable polishing speed depending on abrasive particles. The pH of the polishing slurry composition may have an acidic pH range of 1 to 12, preferably, 1 to 6.

The polishing slurry composition may have a zeta potential of −1 mV to −100 mV, preferably, a zeta potential of −10 mV to −70 mV. When an absolute value of the zeta potential is great, the particles have strong forces pushing each other and do not cohere well. Thus, the polishing slurry composition may exhibit a high zeta potential absolute value even in an acidic region, and thus implement a high dispersion stability and an excellent polishing performance.

The polishing slurry composition may be applied to a polishing process of a semiconductor device and a display device.

The polishing slurry composition may be applied to a planarization process of a semiconductor device and a display device for a film to be polished, that is, a thin film including at least one of an insulation film, a metal film, a metal oxide film, and an inorganic oxide film. For example, the polishing slurry composition may be applied to a planarization process of a semiconductor device to which the insulation film, the metal film, the metal oxide film, and/or the inorganic oxide film is applied and a display device to which the inorganic oxide film is applied.

The insulation film may be a silicon or silicon oxide film, and the metal film and the metal oxide film may each include at least one of Indium (In), tin (Sn), silicon (Si), titanium (Ti), vanadium (V), gadolinium (Gd), gallium (Ga), manganese (Mn), iron (Fe), cobalt (Co), copper (Cu), zinc (Zn), zirconium (Zr), hafnium (Hf), aluminum (Al), niobium (Nb), nickel (Ni), chromium (Cr), molybdenum (Mo), tantalum (Ta), ruthenium (Ru), tungsten (W), titanium (Ti), neodymium (Nd), rubidium (Rb), gold (Au), and platinum (Pt).

The inorganic oxide film may include an oxide, a nitride, or both including at least one of Indium (In), tin (Sn), silicon (Si), titanium (Ti), vanadium (V), gadolinium (Gd), gallium (Ga), manganese (Mn), iron (Fe), cobalt (Co), copper (Cu), zinc (Zn), zirconium (Zr), hafnium (Hf), aluminum (Al), niobium (Nb), nickel (Ni), chromium (Cr), molybdenum (Mo), tantalum (Ta), ruthenium (Ru), tungsten (W), aluminium (Al), antimony (Sb), iridium (Ir), and nickel (Ni), and may be doped with halogen. For example, the inorganic oxide film may include at least one of fluorine doped tin oxide (FTO, SnO₂:F), indium tin oxide (ITO), indium zinc oxide (IZO), indium gallium zinc oxide (IGZO), Al-doped ZnO (AZO), aluminum gallium zinc oxide (AGZO), Ga-doped ZnO (GZO), indium zinc tin oxide (IZTO), indium aluminum zinc oxide (IAZO), indium gallium tin oxide (IGTO), antimony tin oxide (ATO), gallium zinc oxide (GZO), IZO nitride (IZON), SnO₂, ZnO, IrOx, RuOx, and NiO.

The planarization process of the semiconductor device and the display device may be further applied to nitride films of the elements mentioned above, for example, a nitride film such as a SiN film, high-permittivity films such as Hf-based, Ti-based, and Ta-based oxide films, semiconductor films such as silicon, amorphous silicon, SiC, SiGe, Ge, GaN, GaP, GaAs, and organic semiconductor films, phase change films of a GeSbTe film, and polymer resin films such as polyimide-based, polybenzoxazole-based, acrylic-based, epoxy-based, and phenol-based films.

The display device may be a substrate or a panel, a TFT, or an organic electroluminescent display device.

The polishing slurry composition may be further applied to a polishing process of a substrate including at least one of glass, silicon, SiC, SiGe, Ge, GaN, GaP, GaAs, sapphire, and plastic.

The film to be polished may be polished using the polishing slurry composition at a speed of greater than or equal to 100 Å/min, greater than or equal to 500 Å/min, greater than or equal to 1000 Å/min, or greater than or equal to 2000 Å/min.

The polishing slurry composition may exhibit a high polishing selectivity with respect to the film to be polished, and a selectivity of the film to be polished and the insulation film may be 10:1 to 100:1.

A degree of planarization of a surface of the film to be polished after polishing is performed using the slurry composition may be less than or equal to 5%.

After the film to be polished is polished using the polishing slurry composition, a peak to valley (PV) value of the surface thereof may be less than or equal to 100 nm, and a roughness of the surface thereof may be less than or equal to 10 nm. The PV value and a degree of the roughness may be measured using a scanning probe microscopy.

A transparency of a device after the film to be polished is polished using the slurry composition may increase by 5% or more.

Hereinafter, the example embodiments will be described in detail with reference to the following examples and comparative examples. However, the technical idea of the present invention is not limited thereto.

### Example 1: Preparation of Fe Ion-Substituted Colloidal Silica Abrasive Particles

A mixture solution of 3 wt % of colloidal silica abrasive particles, 0.05 wt % of ferric nitrate (Fe(NO₃)₃), and 0.1 wt % of sodium nitrate (NaNO₃) was added. Then, titration was performed using sodium hydroxide (NaOH) until a pH reached 10. The mixture solution containing pH-adjusted colloidal silica was placed in a hydrothermal reactor and subjected to hydrothermal reaction at 140° C. for 24 hours such that Fe ion-substituted colloidal silica abrasive particles were prepared.

### Example 2: Polishing Slurry Composition Including Fe Ion-Substituted Colloidal Silica Abrasive Particles

A polishing slurry composition of pH 2.5 was prepared by adding 4 wt % of the Fe ion-substituted colloidal silica abrasive particles of Example 1, 0.5 wt % of hydrogen peroxide as an oxidizer, 0.1 wt % of malonic acid as a chelating agent, and nitric acid as a pH adjusting agent.

### Example 3: Polishing Slurry Composition Including Fe Ion-Substituted Colloidal Silica Abrasive Particles

A polishing slurry composition was prepared in the same manner as in Example 2, except that 1.00 wt % of the chelating agent was contained.

### Example 4: Polishing Slurry Composition Including Fe Ion-Substituted Colloidal Silica Abrasive Particles

A polishing slurry composition was prepared in the same manner as in Example 2, except that 6 wt % of the Fe ion-substituted colloidal silica abrasive particles and 0.07 wt % of the chelating agent were contained.

### Example 5: Polishing Slurry Composition Including Fe Ion-Substituted Colloidal Silica Abrasive Particles

A polishing slurry composition was prepared in the same manner as in Example 2, except that 0.5 wt % of the Fe ion-substituted colloidal silica abrasive particles and 0.5 wt % of the chelating agent were contained.

### Example 6: Polishing Slurry Composition Including Fe Ion-Substituted Colloidal Silica Abrasive Particles

A polishing slurry composition of pH 2.5 was prepared by adding 1.5 wt % of the Fe ion-substituted colloidal silica abrasive particles of Example 1, 1.5 wt % of hydrogen peroxide as an oxidizer, 0.1 wt % of malonic acid as a chelating agent, and nitric acid as a pH adjusting agent.

### Example 7: Polishing Slurry Composition Including Fe Ion-Substituted Colloidal Silica Abrasive Particles

A polishing slurry composition was prepared in the same manner as in Example 6, except that 4.0 wt % of hydrogen peroxide was applied.

### Comparative Example 1

General Colloidal Silica Abrasive Particles Available on the Market were Prepared.

### Comparative Example 2: Polishing Slurry Composition of General Colloidal Silica Abrasive Particles

A polishing slurry composition was prepared in the same manner as in Example 2, except that colloidal silica abrasive particles available on the market were used and that 2 wt % of the abrasive particles were applied without applying a chelating agent.

### Comparative Example 3: Polishing Slurry Composition of General Colloidal Silica Abrasive Particles

A polishing slurry composition was prepared in the same manner as in Example 6, except that colloidal silica abrasive particle available on the market were used.

(1) Verification of Fe Ion Substitution

To verify whether Fe ion substitution in the Fe ion-substituted colloidal silica abrasive particles of Example 1 was performed well, the Fe ion-substituted colloidal silica abrasive particles of Example 1 were centrifuged, a cake of the particles was dried at 110° C. for 24 hours and mixed with KBr to prepare a pellet, and measurement was performed using an infrared spectroscope. Infrared absorption spectrums of the Fe ion-substituted colloidal silica abrasive particles of Example 1 and the silica abrasive particles of Comparative Example 1 were measured. The infrared absorption spectrums, in which a horizontal axis denotes a wave number and a vertical axis denotes a transmittance, show a Si—O—Fe bonding peak in 668 cm⁻¹. This analysis teaches that Fe-substitution was performed well.

(2) Evaluation of Dispersion Stability (Change in Zeta Potential).

To evaluate the dispersion stabilities of the abrasive particles of Example 1 and Comparative Example 1, initial zeta potentials of the abrasive particles of Example 1 and Comparative Example 1 and their zeta potentials after 10 days were compared. Table 1 shows a result of comparing the initial zeta potentials of the abrasive particles of Example 1 and Comparative Example 1 and their zeta potentials after 10 days.

TABLE 1

| | Initial zeta | Zeta potential | |
|---|---|---|---|
| | potential (mV) | (mV) after 10 days | Remarks |
| Example 1 | −22.4 | −17.9 | Stable |
| Comparative | +1.5 | +0.2 | Cohering |
| Example 1 | | | |

Referring to Table 1, it may be verified that the Fe ion-substituted silica abrasive particles exhibited a high zeta potential absolute value even after 10 days and thus, have a high dispersion stability when compared to the abrasive particles of Comparative Example 1.

(3) Evaluation of Polishing Characteristics

(i) An ITO film containing substrate was polished using the polishing slurry compositions of the examples and the comparative examples under the polishing conditions as described below.

[Polishing Conditions]

1. Polishing device: CETR CP-4 of Bruker

2. Wafer: 6 cm×6 cm ITO film transparent substrate

3. Platen pressure: 3 psi

4. Spindle speed: 69 rpm

5. Platen speed: 70 rpm

6. Flow rate: 100 ml/min

To evaluate the polishing characteristics, polishing speeds and degrees of planarization after the ITO film substrate was polished using the polishing slurry compositions of Examples 2 through 5 and Comparative Example 2 were compared. Table 2 shows the polishing speeds and the degrees of planarization after the ITO film substrate was polished using the polishing slurry compositions of Examples 2 through 5 and Comparative Example 2.

TABLE 2

| | | Abrasive | | | | Transparency |
|---|---|---|---|---|---|---|
| | | particles | Chelating | Polishing | Degree of | change |
| | Abrasive | content | agent content | speed | planarization | (After polishing/ |
| | particles type | (wt %) | (wt %) | (Å/min) | (%) | Before polishing) |
| Example 2 | Fe-substituted | 4.0 | 0.10 | 503 | 3% | +15% |
| | colloidal silica | | | | | |
| Example 3 | Fe-substituted | 4.0 | 1.00 | 610 | 2% | +18% |
| | colloidal silica | | | | | |
| Example 4 | Fe-substituted | 6.0 | 0.07 | 671 | 2% | +20% |
| | colloidal silica | | | | | |
| Example 5 | Fe-substituted | 0.5 | 0.50 | 406 | 5% | +13% |
| | colloidal silica | | | | | |
| Comparative | General | 2.0 | 0.00 | 52 | 17% | +2% |
| Example 2 | colloidal silica | | | | | |

Referring to Table 2, it may be verified that when using the polishing slurry compositions, of Examples 2 through 5, to which the Fe ion-substituted colloidal silica was applied, the polishing speeds and the degrees of planarization with respect to an ITO film were all excellent, and scratch defects were minimized, whereby the transparencies of the substrate improved.

(ii) A tungsten film containing substrate was polished using the polishing slurry compositions of the examples and the comparative examples under the polishing conditions as described below.

[Polishing Conditions]

1. Polishing device: KCTech ST-01

2. Platen speed: 100 rpm

3. Carrier speed: 103 rpm

4. Wafer pressure: 3.0 psi

5. Slurry flow rate: 250 ml/min

6. Pad: IC 1000

TABLE 3

| | | Abrasive | Hydrogen | | |
|---|---|---|---|---|---|
| | | particles | peroxide | | |
| | Abrasive | content | content | W RR | Ox RR |
| | particles type | (wt %) | (wt %) | (Å/min) | (Å/min) |
| Example 6 | Fe-substituted | 1.5 | 1.5 | 1,154 | 169 |
| | colloidal silica | | | | |
| Example 7 | Fe-substituted | 1.5 | 4.0 | 3,180 | 67 |
| | colloidal silica | | | | |
| Comparative | General | 1.5 | 1.5 | 431 | 243 |
| Example 3 | colloidal silica | | | | |

Referring to Table 3, it may be verified that when using the polishing slurry compositions, of Examples 6 and 7, to which the Fe ion-substituted colloidal silica was applied, a high polishing rate and a high polishing selectivity with respect to a tungsten film were provided.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A polishing slurry composition, comprising:
iron-substituted abrasive particles;
a pH adjusting agent; and
a chelating agent, an oxidizer, or both.

2. The polishing slurry composition of claim 1, wherein the iron-substituted abrasive particles are included in the slurry composition in an amount of 0.0001 parts by weight to 20 parts by weight.

3. The polishing slurry composition of claim 1, wherein the iron-substituted abrasive particles are included in the slurry composition in an amount of more than 0.5 parts by weight and less than or equal to 5 parts by weight.

4. The polishing slurry composition of claim 1, wherein the iron-substituted abrasive particles range in size from 10 nm to 300 nm.

5. The polishing slurry composition of claim 1, wherein the iron-substituted abrasive particles are iron-substituted at an atomic site positioned in a length region of less than or equal to 30% from a surface of the iron-substituted abrasive particles, in a length (100%) from the surface to a center of the iron-substituted abrasive particles.

6. The polishing slurry composition of claim 1, wherein the iron-substituted abrasive particles include at least one selected from the group consisting of a metal oxide, and a metal oxide coated with an organic substance or an inorganic substance,
the metal oxide is in a colloidal state, and
the metal oxide includes at least one selected from the group consisting of silica, ceria, zirconia, alumina, titania, barium titania, germania, manganese, and magnesia.

7. The polishing slurry composition of claim 1, wherein the iron-substituted abrasive particles include an iron ion having a tetrahedral coordination, and
the iron-substituted abrasive particles include a metal (M)-O—Fe bond, a metal (M)-Fe bond, or both, M being selected from Si, Ce, Zr, Al, Ti, Ba, Ge, Mn, and Mg.

8. The polishing slurry composition of claim 1, wherein the iron-substituted abrasive particles have a zeta potential of −1 mV to −100 mV at a pH of 1 to 12.

9. The polishing slurry composition of claim 1, wherein the iron-substituted abrasive particles include particles with a single size of 10 nm to 300 nm or mixed particles with at least two different sizes of 10 nm to 300 nm.

10. The polishing slurry composition of claim 1, wherein the iron-substituted abrasive particles include particles with a first size of 10 nm to 150 nm and a second size of 150 nm to 300 nm.

11. The polishing slurry composition of claim 1, wherein the chelating agent includes an organic acid,
the organic acid includes at least one selected from the group consisting of citric acid, malic acid, maleic acid, malonic acid, oxalic acid, succinic acid, lactic acid, tartaric acid, adipic acid, pimelic acid, suberic acid, azelaic acid, sebacic acid, maleic acid, fumaric acid, acetic acid, adipic acid, butyric acid, capric acid, caproic acid, caprylic acid, glutaric acid, glycolic acid, formic acid, lauric acid, myristic acid, palmitic acid, phthalic acid, propionic acid, pyruvic acid, stearic acid, and valeric acid, and
the chelating agent is included in the slurry composition in an amount of 0.00001 parts by weight to 10 parts by weight.

12. The polishing slurry composition of claim 1, wherein the oxidizer includes at least one selected from the group consisting of hydrogen peroxide, urea hydrogen peroxide, urea, percarbonate, periodic acid, periodate, perchloric acid, perchlorate, perbromic acid, perbromate, perboric acid, perborate, permanganic acid, permanganate, persulfate, bromate, chlorate, chlorite, chromate, iodate, iodic acid, ammonium peroxodisulfate, benzoyl peroxide, calcium peroxide, barium peroxide, sodium peroxide, and carbamide peroxide, and
the oxidizer is included in the slurry composition in an amount of 0.00001 parts by weight to 10 parts by weight.

13. The polishing slurry composition of claim 1, wherein the pH adjusting agent includes an acidic substance or a basic substance,
the acidic substance includes at least one selected from the group consisting of nitric acid, hydrochloric acid, phosphoric acid, sulfuric acid, hydrofluoric acid, bromic acid, iodic acid, formic acid, malonic acid, maleic acid, oxalic acid, acetic acid, adipic acid, citric acid, propionic acid, fumaric acid, salicylic acid, pimelic acid, benzoic acid, succinic acid, phthalic acid, butyric acid, glutaric acid, glutamic acid, glycolic acid, lactic acid, aspartic acid, tartaric acid, and salts thereof, and
the basic substance includes at least one selected from the group consisting of ammonium methyl propanol (AMP), tetra methyl ammonium hydroxide (TMAH), ammonium hydroxide, potassium hydroxide, sodium hydroxide, magnesium hydroxide, rubidium hydroxide, cesium hydroxide, sodium bicarbonate, sodium carbonate, imidazole, and salts thereof.

14. The polishing slurry composition of claim 1, wherein the polishing slurry composition is applied to polishing of a thin film including at least one selected from the group consisting of a silicon oxide film, a metal film, a metal oxide film, and an inorganic oxide film.

15. The polishing slurry composition of claim 1, wherein the polishing slurry composition is applied to a polishing process of a semiconductor device, a display device, or both.

16. The polishing slurry composition of claim 14, wherein the metal film and the metal oxide film each include at least one selected from the group consisting of Indium (In), tin (Sn), silicon (Si), titanium (Ti), vanadium (V), gadolinium (Gd), gallium (Ga), manganese (Mn), iron (Fe), cobalt (Co), copper (Cu), zinc (Zn), zirconium (Zr), hafnium (Hf), aluminum (Al), niobium (Nb), nickel (Ni), chromium (Cr), molybdenum (Mo), tantalum (Ta), ruthenium (Ru), tungsten (W), titanium (Ti), neodymium (Nd), rubidium (Rb), gold (Au), and platinum (Pt).

17. The polishing slurry composition of claim 14, wherein the inorganic oxide film includes at least one selected from the group consisting of fluorine doped tin oxide (FTO, SnO₂:F), indium tin oxide (ITO), indium zinc oxide (IZO), indium gallium zinc oxide (IGZO), Al-doped ZnO (AZO), aluminum gallium zinc oxide (AGZO), Ga-doped ZnO (GZO), indium zinc tin oxide (IZTO), indium aluminum zinc oxide (IAZO), indium gallium tin oxide (IGTO), antimony tin oxide (ATO), gallium zinc oxide (GZO), IZO nitride (IZON), SnO₂, ZnO, IrOx, RuOx, and NiO.

18. The polishing slurry composition of claim 1, wherein a target film is polished using the polishing slurry composition at a speed of greater than or equal to 100 Å/min.

19. The polishing slurry composition of claim 1, wherein a degree of planarization of a surface of a target film after polishing is performed using the slurry composition is less than or equal to 5%.

20. The polishing slurry composition of claim 1, wherein a transparency of a device after a target film is polished using the slurry composition increases by 5% or more when compared to that before the target film is polished.
